(19) United States
(12) Patent Application Publication
(10) Pub. No.: US 2007/0269057 A1
(43) Pub. Date: Nov. 22, 2007

(54) SOUND REPRODUCTION DEVICE AND METHOD FOR AUTOMATIC GAIN CONTROL

(75) Inventors: Rong-Hwa Ding, Shenzhen (CN); Xiao-Guang Li, Shenzhen (CN); Bing Li, Shenzhen (CN); Kuan-Hong Hsieh, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/671,445

(22) Filed: Feb. 5, 2007

(30) Foreign Application Priority Data
May 19, 2006 (CN) 200610060717.0

(51) Int. Cl. H03G 3/00; H03G 9/00

(52) U.S. Cl. 381/107; 381/102

(57) ABSTRACT

The present invention provides a sound reproduction device and method for automatic gain control. The method includes steps of: providing a gain index table for listing a plurality of time period each referencing a predetermined gain value; providing a plug for attaching to an audio signal source, receiving audio signals from the audio signal source, and generating a request signal; receiving the request signal generated by the plug; reading a current time and determining a time period corresponding to the current time; reading a predetermined gain value referenced by the time period in the gain index table; replacing the default gain value with the predetermined gain value referenced by the time period; and amplifying the audio signals received from the audio signal source by the predetermined gain value referenced by the time period, thereby audio energy of the amplified audio signals is proper to a user's hearing.

### BACKGROUND OF THE INVENTION

1. Field of the Invention

The present invention relates to a sound reproduction device and method for automatic gain control, especially to a sound reproduction device and method for automatic gain control according to a current time.

2. Description of Related Art

When compared to the past, the pace of life of has significantly increased. Living in a fast paced society often puts a person under high pressure, thus more easily become discontent. Enjoying music has become one of the most common activity to relax and relieve the high pressure and people are often seen enjoying music while working, commuting, and when resting.

In addition, people generally have regular working schedules and living habits. I.e., the time a person wakes up, works, eats, sleeps, exercises, and so on usually remains somewhat habitual. A person may enjoy listening to different style of music when waking up, working, doing exercise, etc. For example, while at work, a person may prefer to listen to light music at a low volume and listen to music with a fast beat while exercising. Additionally, a person's hearing sensitivity may change according to different time periods of the day. During morning hours, a person's listening sensitivity may be more sensitive after waking up, and less sensitive in the afternoon.

Therefore, what is needed is an system capable of automatically controlling a gain value corresponding to different times of the day, which can automatically play appropriate music at a suitable volume during different time period, thereby making it convenient for people to enjoying music. Especially to drivers that listen music simultaneously, the system can lower the risks of accidents of the people who manually adjust the music volume while driving. Furthermore, if a listener prefers enjoying music at a desired volume corresponding to certain time periods of the day, for example, while waking up, the listener can wake up to soothing music comfortably.

Therefore, a heretofore unaddressed need exists in the industry to overcome the aforementioned deficiencies and inadequacies.

### SUMMARY OF THE INVENTION

The present invention provides a sound reproduction device and method for automatic gain control. The sound reproduction device automatically adjusts a gain value of a gain amplifier according to a time period to which a current time belongs, thereby audio energy of audio signals amplified by the gain amplifier is proper to a user's hearing.

The sound reproduction device includes a plug, a gain amplifier, a clock, a storage unit and a processing unit. The plug is configured for attaching to an audio signal source, receiving audio signals from the audio signal source, and generating a request signal. The gain amplifier amplifies the audio signals, thereby yielding amplified audio signals. The clock is configured for providing time. The storage unit stores a default gain value and a gain index table, the gain index table being for listing a plurality of time period each referencing a predetermined gain value. The processing unit includes a time processing module, a gain read module, a gain update module and a gain adjusting module. In response to the request signal, the time processing module obtains a current time from the clock, and determines a time period corresponding to the current time. The gain read module reads a predetermined gain value referenced by the time period in the gain index table. The gain update module replaces the default gain value with the predetermined gain value referenced by the time period. The gain adjusting module signals the gain amplifier to amplify the received audio signals by the predetermined gain value referenced by the time period.

The automatic gain control method includes the steps of providing a storage unit for storing a default gain value and a gain index table, the gain index table being for listing a plurality of time period each referencing a predetermined gain value; providing a plug for attaching to an audio signal source, receiving audio signals from the audio signal source, and generating a request signal; receiving the request signal generated by the plug; obtaining a current time and determining a time period corresponding to the current time; reading a predetermined gain value referenced by the time period in the gain index table; replacing the default gain value with the predetermined gain value referenced by the time period; and amplifying the audio signals received from the audio signal source by the predetermined gain value referenced by the time period.

Other systems, methods, features, and advantages will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

FIG. 1 is a schematic diagram of a sound reproduction device in accordance with a first preferred embodiment of the present invention;

FIG. 2 is a block diagram of a hardware infrastructure of the sound reproduction device of FIG. 1;

FIG. 3 is a schematic diagram of main function modules of a processing unit of FIG. 2;

FIG. 4 is a flowchart of a preferred automatic gain control method by utilizing the sound reproduction device of FIG. 2;

FIG. 5 is a flowchart of a preferred method of regenerating a predetermined gain value referenced by a time period by utilizing the sound reproduction device of FIG. 2; and

FIG. 6 is a schematic diagram of a sound reproduction device in accordance with a second preferred embodiment of the present invention.

### DETAILED DESCRIPTION OF THE INVENTION

The automatic gain control function of the present invention can be incorporated in a sound reproduction device, such as an earphone and a speaker. The following detailed description of preferred embodiments is made with reference to the attached drawings.

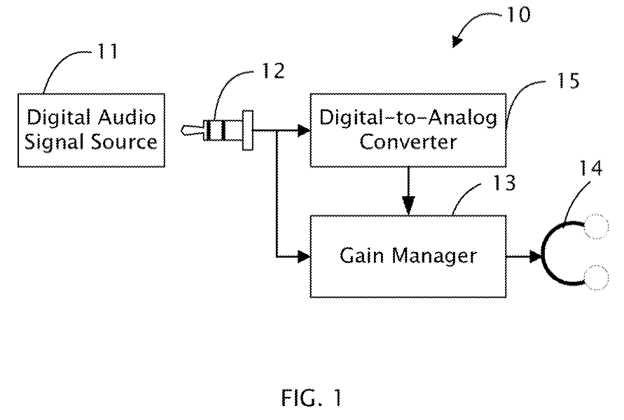

FIG. 1 is a schematic diagram of a sound reproduction device in accordance with a first preferred embodiment of the present invention. The sound reproduction device 10 includes a plug 12, a gain manager 13, a digital-to-analog converter (DAC) 15, and a sound transducer 14.

The plug 12 receives digital audio signals from a digital audio signal source 11, sends a request signal to the gain manager 13, and sends the digital audio signals to the DAC 15. When the gain manager 13 receives the request signal, the gain manager 13 determines a time period corresponding to a current time and reads a predetermined gain value referenced by the time period. The digital audio signal source 11 can be a music player, a radio player, a TV set, and so on.

Synchronously, the DAC 15 converts the digital audio signals received to analog audio signals, and sends the analog audio signals to the gain manager 13. The gain manager 13 amplifies the analog audio signals by the predetermined gain value referenced by the time period, and sends amplified analog audio signals to the sound transducer 14. The sound transducer 14 reproduces sounds corresponding to the amplified analog audio signals.

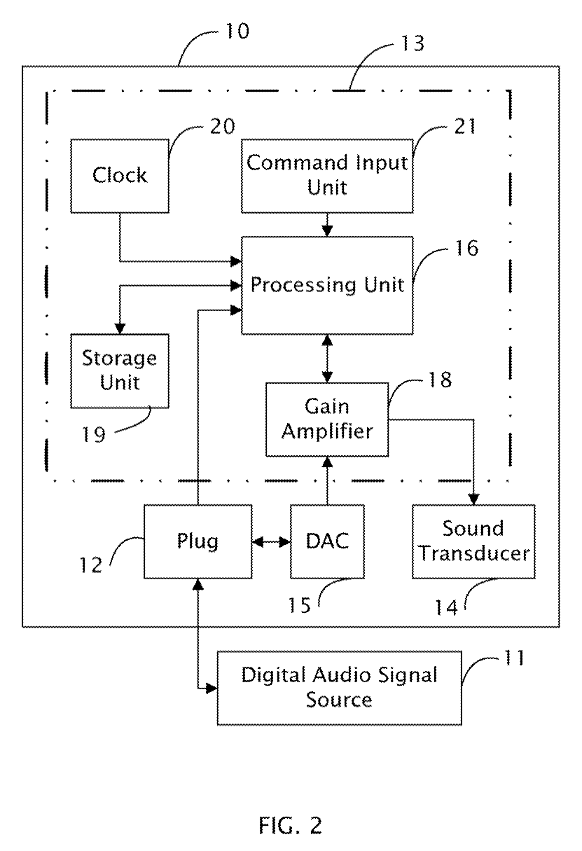

FIG. 2 is a block diagram of a hardware infrastructure of the sound reproduction device of FIG. 1. The gain manager 13 includes a processing unit 16, a gain amplifier 18, a storage unit 19, a clock 20, and a command input unit 21. The processing unit 16 controls a plurality of elements of the gain manager 13, such as, the gain amplifier 18, the storage unit 19, the clock 20, and the command input unit 21. The processing unit 11 can be a digital signal processor (DSP), a central processing unit (CPU), and the like.

The command input unit 21 is configured for receiving operational inputs and then generating a gain adjust signal that signals the processing unit 16 to adjust the current gain value. The storage unit 19 stores a default gain value and a gain index table. The gain index table lists a plurality of time periods each referencing a predetermined gain value. The storage unit 19 may be a flash storage, a hard disk driver, and the like.

The plug 12 is configured for receiving the digital audio signals from the digital audio signal source 11, sending the request signal to the processing unit 16, and for sending the digital audio signals to the DAC 15. When the processing unit 16 receives the request signal, the processing unit 16 reads a current time from the clock 20 and determines the time period corresponding to the current time. The processing unit 16 also reads the predetermined gain value referenced by the time period from the gain index table, signals the gain amplifier 18 to amplify the analog audio signals by the predetermined gain value, and replaces the default gain value with the predetermined gain value.

The DAC 15 is configured for receiving the digital audio signals from the digital audio signal source 11 via the plug 12, converting the digital audio signals to the analog audio signals, and sending the analog audio signals to the gain amplifier 18.

The gain amplifier 18 is configured for amplifying the analog audio signals received from the DAC 14 by the default gain value stored. The sound transducer 14 is adapted for producing the sounds corresponding to the analog audio signals amplified by the gain amplifier 18.

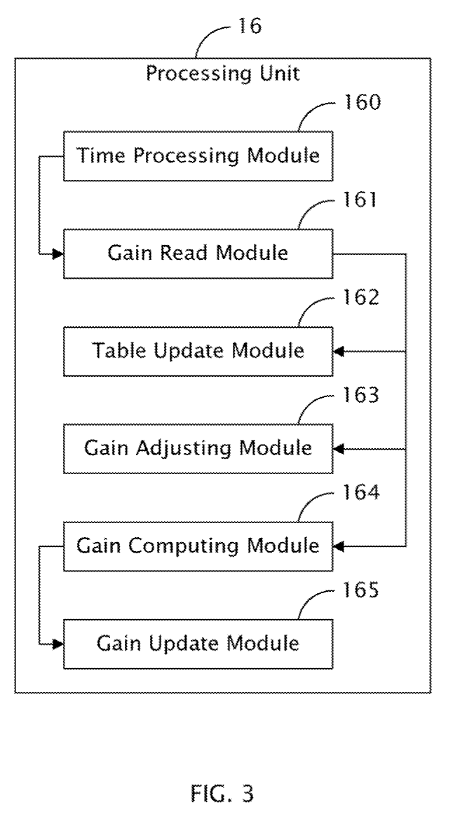

Referring to FIG. 3, the processing unit 16 further includes a time processing module 160, a gain read module 161, a table update module 162, a gain adjusting module 163, a gain computing module 164 and a gain update module 165.

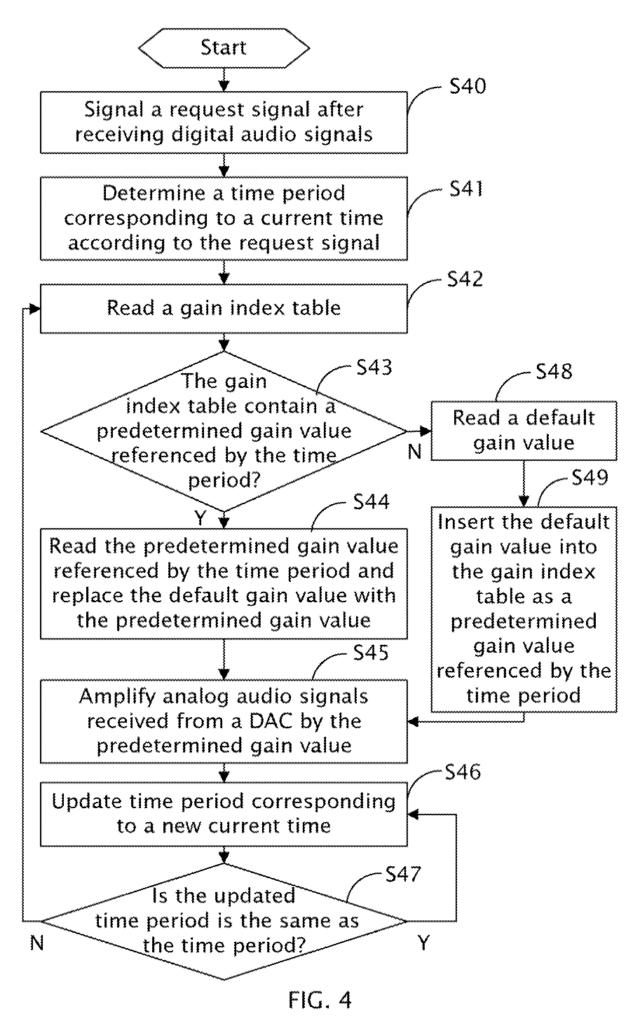

FIG. 4 is a flowchart of a preferred automatic gain control method by utilizing the sound reproduction device 10 of FIG. 2. Referring to FIG. 3, in step S40, the plug 12 sends the request signal to the processing unit 16 after receiving the digital audio signals from the digital audio signal source 11.

In step S41, the time processing module 160 obtains the current time from the clock 20, and determines the time period corresponding to the current time.

In step S42, the gain read module 161 reads the gain index table stored in the storage unit 19.

In step S43, the gain read module 161 determines whether the gain index table contains the predetermined gain value referenced by the time period.

If the gain index table does not contain the predetermined gain value, in step S48, the gain read module 161 reads the default gain value stored in the storage unit 19.

In step S49, the table update module 162 inserts the default gain value into the gain index table as the predetermined gain value referenced by the time period, and then the procedure goes to step S45.

In step S43, if the gain index table contains the predetermined gain value referenced by the time period, in step S44, the gain read module 161 reads the predetermined gain value referenced by the time period from the gain index table, and the gain update module 165 replaces the default gain value stored in the storage unit 19 with the predetermined gain value referenced by the time period.

In step S45, the gain adjusting module 163 signals the gain amplifier 18 to amplify the analog audio signals received from the DAC 15 by the predetermined gain value.

In step S46, the time processing module 160 updates the time period corresponding to a new current time obtained from the clock 20 thereby yielding an updated time period.

In step S47, the time processing module 160 determines whether the updated time period is the same as the time period.

If the updated time period is the same as the time period, the procedure goes to step S46; otherwise, the procedure goes to step S42. The step S42 to step S47 is performed recursively until the plug 12 stops receiving the digital audio signals.

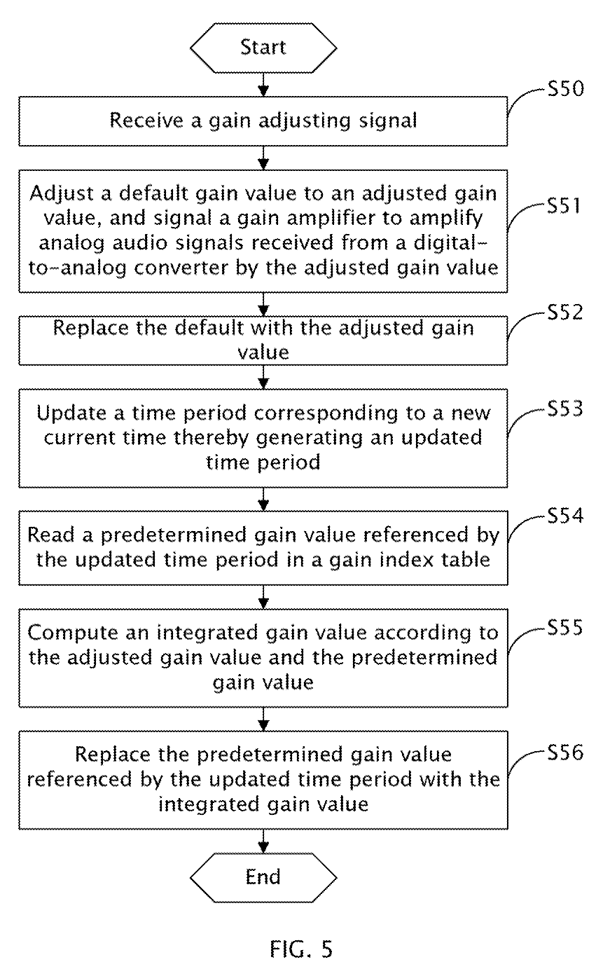

FIG. 5 is a flowchart of a preferred method of retrieving the predetermined gain value referenced by the time period by utilizing the sound reproduction device 10 of FIG. 2. Referring to FIG. 3, in step S50, the processing unit 16 receives the adjusting command from the command input unit 21.

In step S51, the gain adjusting module 163 adjusts the default gain value stored in the storage unit 19 to an adjusted gain value, and signals the gain amplifier 18 to amplify the analog audio signals received from the DAC 15 by the adjusted gain value.

In step S52, the gain update module 165 replaces the default gain value stored in the storage unit 19 with the adjusted gain value.

In step S53, the time processing module 160 updates the time period corresponding to the new current time obtained from the clock 20 thereby yielding the updated time period.

In step S54, the gain read module 161 reads the predetermined gain value referenced by the updated time period.

In step S55, the gain computing module 164 assigns a weight value to the predetermined gain value and the adjusted gain value, multiplies the predetermined gain value and the adjusted gain value by the weight value assigned, thereby obtaining two products, and totals the two products to obtain an integrated gain value.

In step S56, the gain update module 165 replaces the predetermined gain value referenced by the updated time period in the gain index table with the integrated gain value.

In an alternative embodiment, the gain update module 165 directly replaces the predetermined gain value referenced by the time period in the gain index table with the adjusted gain value.

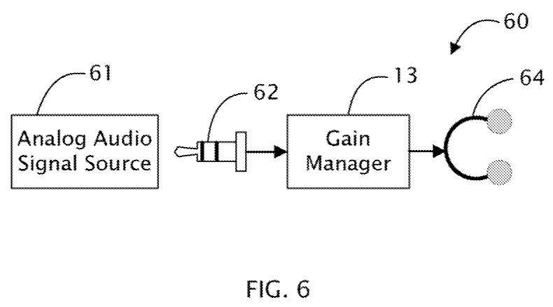

FIG. 6 is a block diagram of a hardware infrastructure of the sound reproduction device 60 in accordance with a second embodiment of the present invention. The sound reproduction device 60 of the second embodiment is the same as that of the first preferred embodiment, except that the plug 62 receives analog audio signals from the analog audio signal source 61. Therefore, the sound reproduction device 60 does not include the digital-to-analog converter 15.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A sound reproduction device for automatic gain control, the sound reproduction device comprising:
a plug configured for attaching to an audio signal source, receiving audio signals from the audio signal source, and generating a request signal;
a gain amplifier configured for amplifying the audio signals received from the audio signal source via the plug, thereby generating amplified audio signals;
a clock configured for providing time;
a storage unit configured for storing a default gain value and a gain index table, the gain index table being for listing a plurality of time period each referencing a predetermined gain value;
a processing unit configured for receiving the request signal from the plug, comprising:
a time processing module for, in response to the request signal, obtaining a current time from the clock, and determining a time period corresponding to the current time;
a gain read module for reading a predetermined gain value referenced by the time period in the gain index table;
a gain update module for replacing the default gain value with the predetermined gain value referenced by the time period; and
a gain adjusting module for signaling the gain amplifier to amplify the received audio signals by the predetermined gain value referenced by the time period.

2. The sound reproduction device according to claim 1, wherein the processing unit further comprises a table update module which inserts the default gain value into the gain index table as the predetermined gain value referenced by the time period, if the gain index table does not list the predetermined gain value referenced by the time period.

3. The sound reproduction device according to claim 1, wherein the processing unit further comprises a gain computing module which computes an integrated gain value according to the predetermined gain value referenced by the time period and an adjusted gain value, after the default gain value is adjusted to the adjusted gain value, and then the gain update module replaces the predetermined gain value referenced by the time period in the gain index table with the integrated gain value.

4. The sound reproduction device according to claim 3, wherein the gain computing module assigns a weight value respectively to the predetermined gain value referenced by the time period and the adjusted gain value, multiplies the predetermined gain value referenced by the time period and the adjusted gain value by the corresponding weight value assigned, thereby obtaining two products, and totals the two products to obtain the integrated gain value.

5. The sound reproduction device according to claim 1, wherein the gain update module replaces the predetermined gain value referenced by the time period in the gain index table with an adjusted gain value, after the default gain value is adjusted to the adjusted gain value.

6. The sound reproduction device according to claim 1, wherein the audio signals that received by the plug are digital audio signals, the sound reproduction device further comprises a digital-to-analog converter for converting the digital audio signals to analog audio signals, and sending the analog audio signals to the gain amplifier.

7. The sound reproduction device according to claim 1, wherein the audio signals that received by the plug are analog audio signals.

8. An automatic gain control method for a sound reproduction device, the method comprising steps of:
providing a storage unit for storing a default gain value and a gain index table, the gain index table listing a plurality of time period each referencing a predetermined gain value;
providing a plug for attaching to an audio signal source, receiving audio signals from the audio signal source, and generating a request signal;
receiving the request signal generated by the plug;
obtaining a current time and determining a time period corresponding to the current time;
reading a predetermined gain value referenced by the time period in the gain index table;
replacing the default gain value with the predetermined gain value referenced by the time period; and
amplifying the audio signals received from the audio signal source by the predetermined gain value referenced by the time period.

9. The method according to claim 8, further comprising steps of:
reading the default gain value, and
inserting the default gain value into the gain index table as the predetermined gain value referenced by the time period, if the gain index table does not list the predetermined gain value referenced by the time period.

10. The method according to claim 8, further comprising steps of:
receiving a gain adjusting command for adjusting the default gain value;
adjusting the default gain value to an adjusted gain value;
amplifying the audio signals received from the audio signal source by the adjusted gain value;
replacing the default gain value with the adjusted gain value;
updating the time period corresponding to a new current time thereby yielding an updated time period;
reading a predetermined gain value referenced by the updated time period in the gain index table;
computing an integrated gain value according to the predetermined gain value referenced by the updated time period and the adjusted gain value; and
replacing the predetermined gain value referenced by the updated time period in the gain index table with the integrated gain value.

11. The method according to claim 10, wherein computing the integrated gain value comprises steps of:
assigning a weight value respectively to the predetermined gain value referenced by the time period and the adjusted gain value;
multiplying the predetermined gain value referenced by the time period and the adjusted gain value by the corresponding weight value assigned, thereby obtaining two products; and
totaling the two products to obtain the integrated gain value.

12. The sound reproduction device according to claim 8, wherein the audio signals that received by the plug are analog audio signals.

13. The sound reproduction device according to claim 8, wherein the audio signals that received by the plug are digital audio signals.
